(19) United States
(12) Patent Application Publication
(10) Pub. No.: US 2022/0230887 A1
(43) Pub. Date: Jul. 21, 2022

(54) METHODS AND APPARATUS FOR PROCESSING A SUBSTRATE

(71) Applicant: Applied Materials, Inc., Santa Clara, CA (US)

(72) Inventors: Meiyee SHEK, Palo Alto, CA (US); Maximillian CLEMONS, Sunnyvale, CA (US); Srinivas D. NEMANI, Saratoga, CA (US); Nikolaos BEKIARIS, Campbell, CA (US); Ellie YIEH, San Jose, CA (US)

(21) Appl. No.: 17/150,280

(22) Filed: Jan. 15, 2021

(51) Int. Cl. H01L 21/311

(52) U.S. Cl. CPC H01L 21/31116; H01L 21/67069

(57) ABSTRACT

Methods and apparatus for processing a substrate are provided herein. For example, a method includes heating a substrate disposed in an interior volume of a process chamber and having a boron-containing film deposited thereon to a predetermined temperature; and supplying water vapor in a non-plasma state to the interior volume at a predetermined pressure for a predetermined time, while maintaining the substrate at the predetermined temperature to anneal the substrate for the predetermined time and remove the boron-containing film.

### FIELD

Embodiments of the present disclosure generally relate to a methods and apparatus for processing a substrate, and more particularly, to methods and apparatus configured to remove boron-containing films.

### BACKGROUND

Micro-electronic circuits and other micro-scale devices are generally manufactured from a substrate (or wafer), such as a silicon or other semiconductor material wafer. Multiple metal layers are applied onto the substrate to form micro-electronic or other micro-scale components or to provide electrical interconnects. For example, metal layers, e.g., copper, are plated onto the substrate, and form the components and interconnects in a sequence of photolithographic, plating, etching, polishing or other steps. For example, high etch selectivity boron-containing films, e.g., hardmask, are sometimes needed to pattern high aspect ratio capacitor structure. However, the boron-containing films can sometimes be difficult to remove using conventional etch chemistry processes, e.g., using H₂O. Additionally, when using conventional etch chemistry processes, a removal rate of the boron-containing film can be significantly reduced as a boron concentration in the boron-containing film increases.

### SUMMARY

Methods and apparatus for processing a substrate are provided herein. In some embodiments, a method for processing a substrate includes heating a substrate disposed in an interior volume of a process chamber and having a boron-containing film deposited thereon to a predetermined temperature and supplying water vapor in a non-plasma state to the interior volume at a predetermined pressure for a predetermined time, while maintaining the substrate at the predetermined temperature to anneal the substrate for the predetermined time and remove the boron-containing film.

In accordance with at least some embodiments, a non-transitory computer readable storage medium has instructions stored thereon which when executed by a processer perform a method for processing a substrate. The method includes heating a substrate disposed in an interior volume of a process chamber and having a boron-containing film deposited thereon to a predetermined temperature and supplying water vapor in a non-plasma state to the interior volume at a predetermined pressure for a predetermined time, while maintaining the substrate at the predetermined temperature to anneal the substrate for the predetermined time and remove the boron-containing film.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a diagram of an integrated tool for processing a substrate in accordance with at least one embodiment of the present disclosure.

FIG. 2 is a diagram of a high-pressure system in accordance with at least one embodiment of the present disclosure.

FIG. 3 is a schematic side view of a high-pressure processing system in accordance with at least one embodiment of the present disclosure.

FIG. 4 is a flowchart of a method for processing a substrate in accordance with at least one embodiment of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a method and apparatus for processing a substrate are provided herein. For example, methods for removing boron-containing films are described herein. In at least some embodiments, a method can include heating a substrate (e.g., having a boron-containing film deposited thereon) disposed in an interior volume of a process chamber to a predetermined temperature. Water vapor (e.g., steam) in a non-plasma state can be supplied to the interior volume at a predetermined pressure (e.g., a high pressure environment) for a predetermined time, while maintaining the substrate support at the predetermined temperature to anneal the substrate for the predetermined time and remove/strip the boron-containing film. In at least some embodiments, the steam can be mixed with an oxidizer, such as at least one of oxygen O₂, O₃, N₂O, CO₂, or CO, in the high pressure environment to facilitate stripping (e.g., accelerating removal of) the boron-containing film. Unlike conventional boron etching processes, the methods described herein are capable of removing boron-containing films having high concentrations of boron at rates up to 10× faster than conventional boron etching process, e.g., the methods described herein have removal rates equal to >3000 A/min vs. conventional methods which have removal rates equal to <400 A/min.

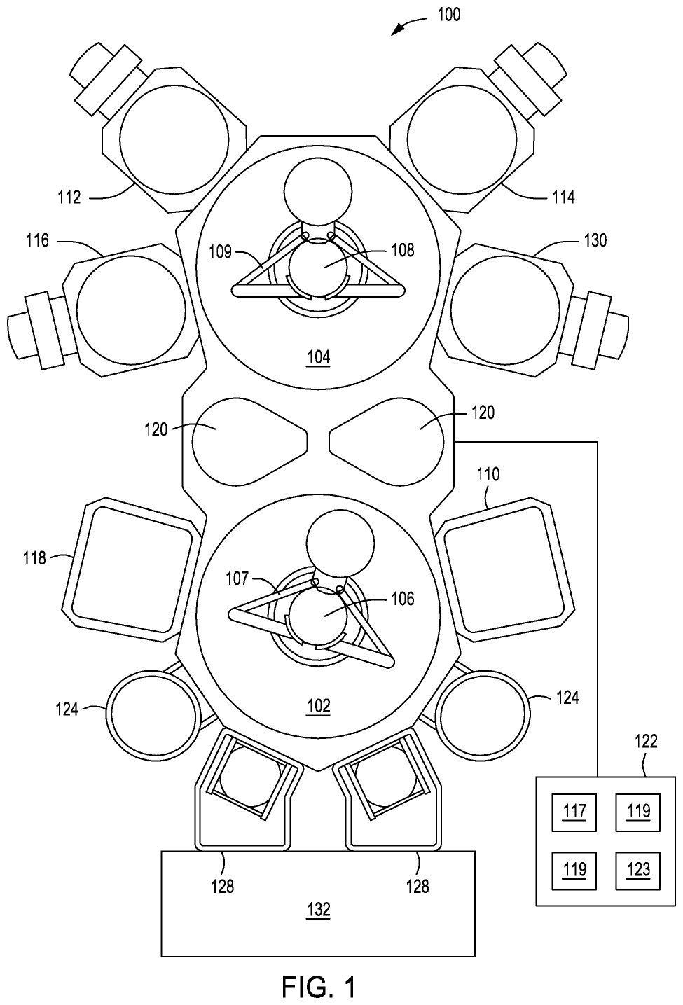

FIG. 1 is a diagram of an integrated tool 100 (e.g., a multi-chamber substrate processing system) for processing a substrate in accordance with at least one embodiment of the present disclosure. The integrated tool 100 is suitable for performing physical vapor deposition, chemical vapor deposition, and/or an annealing process described herein. The integrated tool 100 includes at least one high-pressure processing chamber, e.g., able to operate at pressures above 10 atmospheres, to perform a high-pressure process such as deposition or annealing, and at least one low-pressure processing chamber, e.g., able to operate a pressures below about 100 mTorr, to perform a low-pressure process such as etching, deposition, or thermal treatment. In some implementations the integrated tool 100 is a cluster tool having a central transfer chamber that is at low-pressure and from which multiple processing chambers can be accessed.

Some embodiments of the processes and systems described herein relate to forming layers of material, e.g., metal and metal silicide barriers, for feature definitions. For example, a first metal layer can be deposited on a silicon substrate and annealed to form a metal silicide layer. A second metal layer can then deposited on the metal silicide layer to fill the feature. The annealing process to form the metal silicide layer may be performed in multiple annealing steps.

Continuing with reference to FIG. 1, the integrated tool 100 comprises two transfer chambers 102, 104, transfer robots 106, 108 positioned in the transfer chambers 102, 104, respectfully, and processing chambers 110, 112, 114, 116, 118, disposed on the two transfer chambers 102, 104. The transfer chambers 102, 104 are central vacuum chambers that interface with processing chambers 110, 112, 114, 116, 118. The transfer chamber 102 and the transfer chamber 104 are separated by pass-through chambers 120, which may comprise cooldown or pre-heating chambers. The pass-through chambers 120 also may be pumped down or ventilated during substrate handling when the transfer chamber 102 and the transfer chamber 104 operate at different pressures. For example, the transfer chamber 102 may operate between about 100 mTorr and about 5 Torr, such as about 40 mTorr, and the transfer chamber 104 may operate between about 1×10⁻⁵ Torr and about 1×10⁻⁸ Torr, such as about 1×10⁻⁷ Torr.

The integrated tool 100 is automated by programming a controller 122 (processor). The controller 122 can operate individual operations for each of the chambers of the integrated tool 100 to process a substrate. The controller 122 is configured to control the operation of the integrated tool 100 during processing. The controller 122 comprises a central processing unit 117 (CPU), a memory 119 (e.g., non-transitory computer readable storage medium), and support circuits 123 for the central processing unit 117 and facilitates control of the components of the integrated tool 100. The controller 122 may be one of any form of general-purpose computer processor that can be used in an industrial setting for controlling various chambers and sub-processors. The memory 119 stores software (instructions, source, or object code) that may be executed or invoked to control the operation of the integrated tool 100 in the manner described herein.

The transfer chamber 102 can be coupled with two degas chambers 124, two load lock chambers 128, a pre-clean chamber (e.g., reactive pre-clean chamber), at least one of the processing chambers 110, 112, 114, 130, which can be a physical vapor deposition chamber, such as a long throw physical vapor deposition (PVD) chamber, and the pass-through chambers 120. A pre-clean chamber may be a preclean chamber, commercially available from Applied Materials, of Santa Clara, Calif. Substrates (not shown) are loaded into the integrated tool 100 through load lock chambers 128. For example, a factory interface module 132, if present, would be responsible for receiving one or more substrates, e.g., wafers, cassettes of wafers, or enclosed pods of wafers, from either a human operator or an automated substrate handling system. The factory interface module 132 can open the cassettes or pods of substrates, if applicable, and move the substrates to and from the load lock chambers 128. The processing chambers 110, 112, 114, 116, 118 receive the substrates from the transfer chambers 102, 104, process the substrates, and allow the substrates to be transferred back into the transfer chambers 102, 104. After being loaded into the integrated tool 100, the substrates are sequentially degassed and cleaned in degas chambers 124 and the pre-clean chamber, respectively.

Each of the processing chambers are isolated from the transfer chambers 102, 104 by an isolation valve which allows the processing chambers to operate at a different level of vacuum than the transfer chamber 102 and the transfer chamber 104 and prevents any gasses being used in the processing chambers from being introduced into the transfer chamber. The load lock chambers 128 are also isolated from the transfer chamber 102, 104 with isolation valves (not shown). Each load lock chamber 128 has a door which opens to the outside environment, e.g., opens to the factory interface module 132. In normal operation, a cassette loaded with substrates is placed into the load lock chamber 128 through the door from the factory interface module 132 and the door is closed. The load lock chamber 128 is then evacuated to the same pressure as the transfer chamber 102 and the isolation valve between the load lock chamber 128 and the transfer chamber 102 is opened. The robot in the transfer chamber 102 is moved into position and one substrate is removed from the load lock chamber 128. The load lock chamber 128 is preferably equipped with an elevator mechanism so as one substrate is removed from the cassette, the elevator moves the stack of wafers in the cassette to position another wafer in the transfer plane so that it can be positioned on the robot blade.

The transfer robot 106 in the transfer chamber 102 then rotates with the substrate so that the substrate is aligned with a processing chamber position. The processing chamber is flushed of any toxic gasses, brought to the same pressure level as the transfer chamber, and the isolation valve is opened. The transfer robot 106 then moves the wafer into the processing chamber where it is lifted off the robot. The transfer robot 106 is then retracted from the processing chamber and the isolation valve is closed. The processing chamber then goes through a series of operations to execute a specified process on the wafer. When complete, the processing chamber is brought back to the same environment as the transfer chamber 102 and the isolation valve is opened. The transfer robot 106 removes the wafer from the processing chamber and then either moves it to another processing chamber for another operation or replaces it in the load lock chamber 128 to be removed from the integrated tool 100 when the entire cassette of wafers has been processed.

The transfer robot 106 and the transfer robot 108 include robot arms 107, 109, respectively, that support and move the substrate between different processing chambers. The transfer robot 106 moves the substrate between the degas chambers 124 and at least one of the processing chambers 110, 112, 114, 116, 118, 130, such as pre-clean chamber. The substrate may then be transferred to at least one of the processing chambers 110, 112, 114, 130, such as the long throw PVD chamber for deposition of a material thereon.

The transfer chamber 104 is coupled to a cluster of processing chambers 110, 112, 114, 130. The processing chambers 110, 112 may be chemical vapor deposition (CVD) chambers for depositing materials, such as tungsten, as desired by the operator. An example of suitable CVD chambers are commercially available from Applied Materials, Inc., located in Santa Clara, Calif. The CVD chambers are preferably adapted to deposit materials by atomic layer deposition (ALD) techniques as well as by conventional chemical vapor deposition techniques. The processing chambers 114 and 130 may be rapid thermal annealing (RTA) chambers, or rapid thermal process (RTP) chambers, that can anneal substrates at vacuum or near vacuum pressures. An example of an RTA chamber is commercially available from Applied Materials, Inc., Santa Clara, Calif. Alternatively, the processing chambers 114 and 130 may deposition chambers capable of performing high temperature CVD deposition, annealing processes, or in situ deposition and annealing processes. The PVD processed substrates are moved from the transfer chamber 102 into the transfer chamber 104 via the pass-through chambers 120. Thereafter, the transfer robot 108 moves the substrates between one or more of the processing chambers 110, 112, 114, 130 for material deposition and annealing as required for processing.

RTA chambers (not shown) may also be disposed on the transfer chamber 102 of the integrated tool 100 to provide post deposition annealing processes prior to substrate removal from the integrated tool 100 or transfer to the transfer chamber 104.

While not shown, a plurality of vacuum pumps is disposed in fluid communication with each transfer chamber and each of the processing chambers to independently regulate pressures in the respective chambers. The pumps may establish a vacuum gradient of increasing pressure across the apparatus from the load lock chamber to the processing chambers.

Alternatively or in addition, a plasma etch chamber, such as a plasma etch chamber manufactured by Applied Materials, Inc., of Santa Clara, Calif., may be coupled to the integrated tool 100 or in a separate processing system for etching the substrate surface to remove unreacted metal after PVD metal deposition and/or annealing of the deposited metal. For example, in forming cobalt silicide from cobalt and silicon material by an annealing process, the etch chamber may be used to remove unreacted cobalt material from the substrate surface.

Other etch processes and apparatus, such as a wet etch chamber, can be used in conjunction with the process and apparatus described herein.

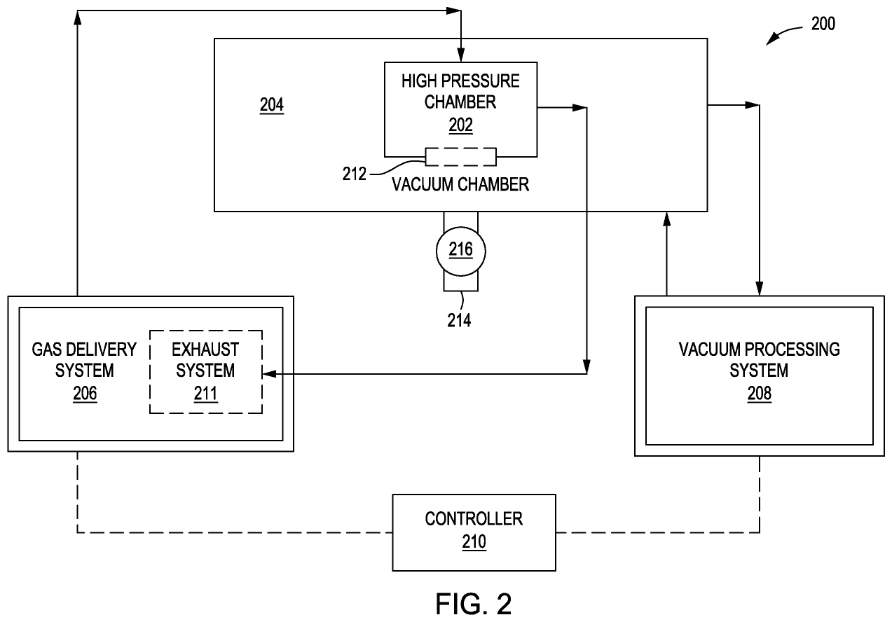

FIG. 2 is a diagram of a high-pressure system 200 in accordance with at least one embodiment of the present disclosure. The high-pressure system 200 is configured to create a high-pressure environment for processing a substrate and a low-pressure environment for the substrate when the substrate is being transferred between processing chambers. The controlled high-pressure system 200 includes a first chamber 202 (e.g., high-pressure chamber) and a second chamber 204 (e.g., vacuum chamber). The first chamber 202 can correspond to one of the processing chambers 110, 112, 114, 116, 118, 130 of the integrated tool 100, and the second chamber 204 can correspond to one of the transfer chambers 102, 104 of the integrated tool 100. Alternatively, one of the processing chambers 110, 112, 114, 116, 118, 130 includes both the first chamber 202 and the second chamber 204. The first chamber 202 corresponds to an inner chamber, and the second chamber 204 corresponds to an outer chamber surrounding the inner chamber.

The pressure within the first chamber 202 can be controlled independently of the pressure in the second chamber 204. If the first chamber 202 and second chamber 204 are distinct from the transfer chambers, the first chamber 202 and second chamber 204 can have pressures that are controlled independently of the pressures within the transfer chambers. The controlled high-pressure system 200 further includes a gas delivery system 206, a vacuum processing system 208, and a controller 210. In some examples, the controller 122 of the integrated tool 100 can include the controller 210.

The second chamber 204 is a low-pressure chamber adjacent to the first chamber 202. In some implementations, the second chamber 204 also surrounds the first chamber 202. The second chamber 204 can correspond to a transfer chamber, e.g., the transfer chamber 102 or the transfer chamber 104, that receives the substrate between different processing chambers. The low-pressure environment of the second chamber 204 can inhibit contamination and/or oxidation of the substrate or the material formed on the substrate.

The gas delivery system 206 is operated to pressurize and depressurize the first chamber 202. The first chamber 202 is a high-pressure processing chamber that receives a processing gas from the gas delivery system 206 and establishes a high pressure, e.g., at a pressure of at least 10 atmospheres. The processing gas can interact with the layer being processed so as to anneal the layer, e.g., by modifying the layer or reacting with the material to form a new layer. For example, the processing gas can include, for example, CO, CO₂, O₂, O₃, or N₂O. In at least some embodiments, the processing gas can be O₂, as described in greater detail below. Alternatively or additionally, the processing gas can be a precursor gas that serves as a source for the material to be formed on the substrate, e.g., for a deposition process. To pressurize the first chamber 202, the gas delivery system 206 introduces the processing gas into the first chamber 202. In some cases, the gas delivery system 206 can also introduce water vapor, e.g., steam, into the first chamber 202 to increase the pressure within the first chamber 202, e.g., to remove boron-containing film from a substrate.

The gas delivery system 206 can include an exhaust system 211 to exhaust the processing gas from the first chamber 202, thereby depressurizing the first chamber 202. The vacuum processing system 208 is operated to control the pressure of the second chamber 204 to be at a vacuum or near-vacuum pressure, e.g., less than 1 mTorr. For example, the vacuum processing system 208 lowers a pressure within the second chamber 204 to near vacuum, thus creating the appropriate low-pressure environment for transfer of the substrate.

A valve assembly 212 between the first chamber 202 and the second chamber 204 isolates the pressure within the first chamber 202 from the pressure within the second chamber 204. The high-pressure environment within the first chamber 202 can thus be separated and sealed from the low-pressure environment within the second chamber 204. The valve assembly 212 is openable to enable the substrate to be transferred from the first chamber 202 directly into the second chamber 204 or to enable the substrate to be transferred from the second chamber 204 directly into the first chamber 202.

The high-pressure system 200 includes a foreline 214 connected to a transfer chamber, e.g., either the transfer chamber 102 or the transfer chamber 104, and connected to an outside environment. An isolation valve 216 is arranged along the foreline 214 to isolate the pressure within the second chamber 204 from the pressure of the outside environment. The isolation valve 216 can be operated to adjust the pressure within the second chamber 204 and to release gases within the second chamber 204. The isolation valve 216 can be operated in conjunction with the vacuum processing system 208 to regulate the pressure within the second chamber 204.

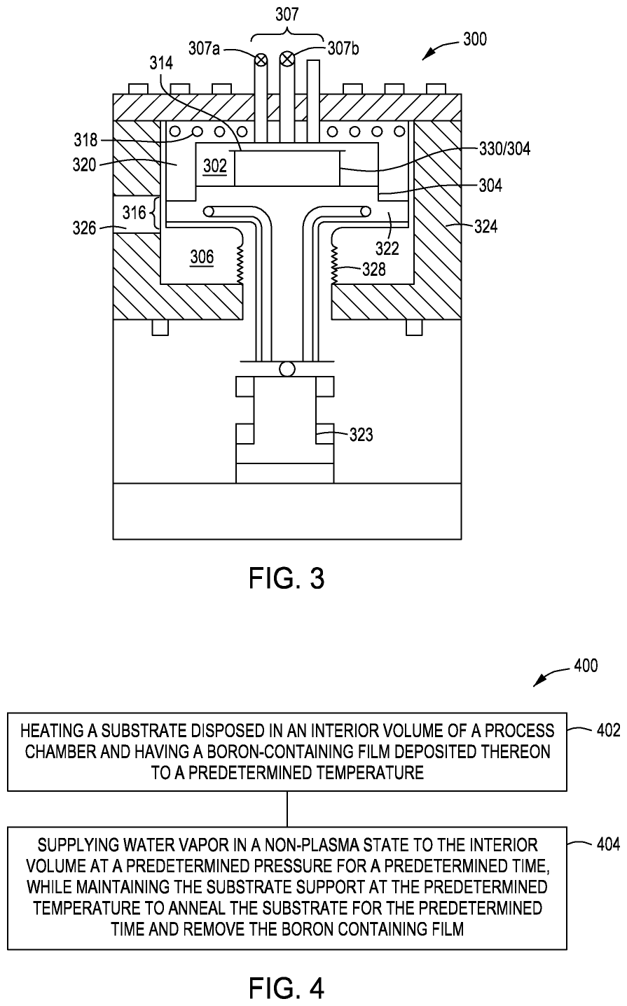

FIG. 3 is a schematic side view of a high-pressure processing system 300 in accordance with at least one embodiment of the present disclosure. The pressure of chambers of high-pressure processing systems can be controlled using systems similar to the high-pressure system 200 described with respect to FIG. 2.

The high-pressure processing system 300 includes a first chamber 302 (e.g., first high-pressure chamber), a pedestal 304 (e.g., substrate support), a second chamber 306 (e.g., low-pressure chamber), and a controller (e.g., the controller 122). The high-pressure processing system 300 further includes a vacuum processing system (not shown) similar to the vacuum processing system 208 and a gas delivery system 307 similar to the gas delivery system 206 described with respect to FIG. 2. For example, the gas delivery system 307 includes an input line 307a and an exhaust line 307b. The processing gas is introduced into the first chamber 302 through the input line 307a, and the processing gas is exhausted from the first chamber 302 through the exhaust line 307b.

The pedestal 304 supports a substrate 314 on which a layer of material is to be processed, e.g., removed, annealed or deposited. The pedestal 304 is positioned or positionable within the first chamber 302. In some implementations, the substrate 314 sits directly on a flat top surface of the pedestal. In some implementations, the substrate 314 sits on pins 330 that project from the pedestal.

The high-pressure processing system 300 includes an inner wall 320, a base 322, and an outer wall 324. The first chamber 302 is provided by a volume within the inner wall 320, e.g., between the inner wall 320 and the base 322. The second chamber 306 is provided by a volume outside the inner wall 320, e.g., between the inner wall 320 and the outer wall 324.

The high-pressure processing system 300 further includes a valve assembly 316 between the first chamber 302 and the second chamber 306 that provides the functionality of the valve assembly 212 of FIG. 2, e.g., operated to isolate the first chamber 302 from the second chamber 306. For example, the valve assembly 316 includes the inner wall 320, the base 322, and an actuator 323 to move the base 322 relative to the inner wall 320. The actuator 323 can be controlled to drive the base 322 to move vertically, e.g., away from or toward the inner wall 320 defining the first chamber 302. A bellows 328 can be used to seal the second chamber 306 from the external atmosphere while permitting the base 322 to move vertically. The bellows 328 can extend from a bottom of the base 322 to a floor of the second chamber 306 formed by the outer wall 324.

When the valve assembly 316 is in a closed position, the base 322 contacts the inner wall 320 such that a seal is formed between the base 322 and the inner wall 320, thus separating the second chamber 306 from the first chamber 302. The second chamber 306 may be referred to as an outer chamber and the first chamber 302 may be referred to as an inner chamber. The actuator 323 is operated to drive the base 322 toward the inner walls 320 with sufficient force to form the seal. The seal inhibits air from the first chamber 302 from being exhausted into the second chamber 306.

When the valve assembly 316 is in an open position, the base 322 is spaced apart from the inner wall 320, thereby allowing air to be conducted between the first chamber 302 and second chamber 306 and also allowing the substrate 314 to be accessed and transferred to another chamber.

Because the pedestal 304 is supported on the base 322, the pedestal 304 is thus also movable relative to the inner walls 320. The pedestal 304 can be moved to enable the substrate 314 to be more easily accessible by the transfer robot. For example, an arm of a transfer robot 106 or 108 (see FIG. 1) can extend through an aperture (or slit) 326 in the outer wall 324. When the valve assembly 316 is in the open position, the robot arm can pass through the gap between the inner wall 320 and the base 322 to access the substrate 314.

The high-pressure processing system 300 includes one or more heating elements 318 configured to apply heat to the substrate 314. The heat from the heating elements 318 can be sufficient to anneal the substrate 314 (or remove boron-containing films therefrom) when the substrate 314 is supported on the pedestal 304 and the processing gas (if used) has been introduced into the first chamber 302. The heating elements 318 may be resistive heating elements. The one or more heating elements 318 may be positioned in, e.g., embedded in, the inner walls 320 defining the first chamber 302, e.g., in a ceiling of the first chamber 302 provided by the inner walls 320. This heats the inner wall 320, causing radiative heat to reach the substrate 314. The substrate 314 can be held by the pedestal 304 in close proximity, e.g., 2-10 mm, to the ceiling to improve transmission of heat from the inner wall 320 to the substrate 314.

However, the one or more heating elements 318 may be arranged in other locations within the high-pressure processing system 300, e.g., within the side walls rather than the ceiling. An example of a heating element 318 includes a discrete heating coil. Instead of or in addition to a heater embedded in the inner wall, a radiative heater, e.g., an infrared lamp, can be positioned outside the first chamber 302 and direct infrared radiation through a window in the inner wall 320. Electrical wires connect an electrical source (not shown), such as a voltage source, to the heating element, and can connect the one or more heating elements 318 to the controller.

The controller is operably connected to the vacuum processing system, the gas delivery system 307, and the valve assembly 316 for controlling operations to process, e.g., to removing/strip, anneal or deposit, the layer of material on the substrate 314. In some implementations, the controller may also be operably connected to other systems. For example, the controller can also be operably connected to one or more of the transfer robots 106, 108, the one or more heating elements 318, and/or the actuator 323. In some cases, the controller 122 shown in FIG. 1 includes the controller of the high-pressure processing system 300.

In processing a layer of material on the substrate 314, the controller can operate the vacuum processing system to depressurize the second chamber 306 to a low-pressure state, e.g., to a state in which the second chamber 306 has a pressure less than 1 atmosphere, to prepare for transfer of the substrate 314 through the second chamber 306. The low-pressure state can be a near-vacuum state, e.g., a pressure less than 1 mTorr. The substrate 314 is moved through the second chamber 306 by a transfer robot, e.g., one of the transfer robots 106, 108, while the second chamber 306 is at the low-pressure so that contamination and oxidation of the substrate 314 can be inhibited. The double walls can help ensure safer processing, e.g., annealing.

The substrate 314 is transferred into the first chamber 302 for processing. To transfer the substrate 314 into the first chamber 302, the controller can operate the valve assembly 316, e.g., open the valve assembly 316 to provide an opening through which the substrate 314 can be transferred into the first chamber 302. The controller can operate the transfer robot to carry the substrate 314 into the first chamber 302 and to place the substrate 314 on the pedestal 304

After the substrate 314 is transferred into the first chamber 302, the controller can operate the valve assembly 316 to close the opening, e.g., close the valve assembly 316, thereby isolating the first chamber 302 and second chamber 306 from one another. With the valve assembly 316 closed, pressures in the first chamber 302 and the second chamber 306 can be set to different values. The controller can operate the gas delivery system 307 to introduce the processing gas into the first chamber 302 to pressurize the first chamber 302 and to form the layer of material onto the substrate 314. The introduction of the processing gas can increase the pressure within the first chamber 302 to, for example, 10 atmospheres or more.

The processing gas interacts with water vapor to remove material from a substrate, and the proper temperature and pressure conditions in the first chamber 302 can cause the removal of the material to occur. and the proper temperature and pressure conditions in the first chamber 302 can cause the deposition of the material to occur. Alternatively or additionally, the processing gas interacts with the material on the substrate as to anneal the material, e.g., by modifying the layer or reacting with the material to form a new layer. Alternatively or additionally, the processing gas can include the material to be deposited onto the substrate 314, and the proper temperature and pressure conditions in the first chamber 302 can cause the deposition of the material to occur. During the processing of the substrate, the controller can operate the one or more heating elements 318 to add heat to the substrate 314 to facilitate removal, anneal, and/or deposition of the layer of material on the substrate 314.

When modification or formation of the layer of material on the substrate 314 is complete, the substrate 314 can be removed from the first chamber 302 using the transfer robot and, if necessary, transferred to a subsequent process chamber. Alternatively, the substrate 314 is transferred into a load lock chamber, e.g., one of the load lock chambers 128. To prepare for transfer of the substrate 314 out of the first chamber 302, the controller can operate the exhaust system of the gas delivery system 307 to depressurize the first chamber 302 before the valve assembly 316 is opened. In particular, before the substrate 314 is transferred out of the first chamber 202, the processing gas is exhausted from the first chamber 302 to reduce the pressure within the first chamber 202. The pressure can be reduced to a near-vacuum pressure such that the pressure differential between the first chamber 302 and the second chamber 306 can be minimized.

To enable the substrate 314 to be transferred out of the first chamber 302, the controller can open the valve assembly 316. The opened valve assembly 316 provides an opening through which the substrate 314 is moved to be transferred into the second chamber 306. In particular, the opened valve assembly 316 enables the substrate 314 to be transferred directly into the second chamber 306, e.g., into the low-pressure environment of the second chamber 306. The controller can then operate the transfer robot to transfer the substrate 314 to another portion of a processing platform, e.g., the integrated tool 100. For example, the substrate 314 is first transferred directly into the second chamber 306 and then is transferred to the appropriate processing chamber for further processing or to the load lock chamber to remove the substrate from the processing platform.

FIG. 4 is a flowchart of a method 400 for processing a substrate. The method 400 can be performed in a single substrate (wafer) chamber, such as a plasma chamber (e.g., a plasma reaction, either in-situ or remote plasma), a UV cure chamber, a batch furnace, etc.

At 402, the method 400 includes heating a substrate disposed in an interior volume of a process chamber and having a boron-containing film (e.g., hardmask) deposited thereon to a predetermined temperature. For example, the substrate 314 can be disposed in an interior volume of the first chamber 302, which can be under vacuum (e.g., pumped down to less than 100 mTorr and isolated), and placed on a substrate support (e.g., the pedestal 304) at set temperature. In at least some embodiments, the boron-containing film comprises at least one of carbon, hydrogen, and/or oxygen. For example, the boron-containing film (e.g., having a boron concentration of about 65% to about 85%) can comprise boron oxide, amorphous boron, or a mixture of boron and carbon. Additionally, at 402, the substrate can be heated to a predetermined temperature of about 400° C. to about 500° C. For example, in at least some embodiments, the predetermined temperature is about 500° C. In at least some embodiments, the interior volume of the first chamber 302 can be preheated to the predetermined temperature prior to loading the substrate 314 therein. Alternatively, the substrate 314 can be loaded into the first chamber 302 and then heated to the predetermined temperature.

Next, at 404, the method 400 includes supplying water vapor in a non-plasma state to the interior volume at a predetermined pressure for a predetermined time, while maintaining the substrate support at the predetermined temperature to anneal the substrate for the predetermined time and remove the boron containing film. For example, under control of a controller (e.g., the controller 122), the gas delivery system 206 is configured to introduce water vapor, e.g., high-pressure steam, into the first chamber 302, e.g., to remove a boron-containing film from the substrate 314. For example, the high-pressure water vapor can be provided at about 20 bars to about 60 bars. In at least some embodiments, the high-pressure water vapor can be provided at about 30 bars.

Additionally, the inventors have found that by mixing the high-pressure water vapor with one or more process gases (e.g., an oxidizer) a removal/strip rate of the boron-containing film can be increased, e.g., accelerating removal of the boron-containing film by more than three times of that without adding a process gas. Accordingly, at 404, one or more process gases can be supplied into the first chamber 302 while the high-pressure water vapor is being supplied to the interior volume of the first chamber 302 to facilitate removing the boron-containing film. For example, the one or more process gases can be at least one of O₂, O₃, N₂O, CO₂, or CO while the water vapor is being supplied to the interior volume. In at least some embodiments, the process gas can be 02, which can be provided at a pressure of about 10 bars to about 50 bars. In at least some embodiments, the 02 can be being supplied to the interior volume at a pressure of about 45 bars.

At 404, the high-pressure water vapor can be applied to the heated substrate 314 while the substrate 314 is being annealed at a predetermined time of about 2 minutes to about 30 minutes. For example, in at least some embodiments, such as when the high-pressure water vapor is being applied in conjunction with the one or more process gases, the predetermined time can be about 5 minutes. Likewise, in at least some embodiments, such as when the high-pressure water vapor applied without the one or more process gases, the predetermined time can be slightly higher, such as about 5 minutes. As can be appreciated, one or more parameters (e.g., water pressure, substrate temperature, etc.) may be adjusted to increase/decrease the predetermined time at which the substrate is annealed

Furthermore, prior to supplying the water vapor at 404, the method 400 can include heating a chamber wall of the process chamber to a temperature of about 250° C. to about 300° C. For example, the inner wall 320 of the first chamber 302 can be heated to a temperature of about 250° C. to about 300° C. prevent steam from condensing on the inner wall 320.

After the method 400 is completed, the substrate 314 can be transferred to the loadlock to cool down before unloading.

While the foregoing is directed to embodiments of the present disclosure, other and further embodiments of the disclosure may be devised without departing from the basic scope thereof.

1. A method of processing a substrate, comprising:
heating a substrate disposed in an interior volume of a process chamber and having a boron-containing film deposited thereon to a predetermined temperature; and
supplying water vapor in a non-plasma state to the interior volume at a predetermined pressure for a predetermined time, while maintaining the substrate at the predetermined temperature to anneal the substrate for the predetermined time and remove the boron-containing film.

2. The method of claim 1, further comprising supplying at least one of O₂, O₃, N₂O, CO₂, or CO while the water vapor is being supplied to the interior volume.

3. The method of claim 2, wherein supplying the at least one of at least one of O₂, O₃, N₂O, CO₂, or CO is performed at a pressure of about 10 bars to about 50 bars.

4. The method of claim 1, wherein the predetermined temperature is about 400° C. to about 500° C.

5. The method of claim 1, wherein the predetermined temperature is about 500° C.

6. The method of claim 1, wherein the predetermined pressure is about 20 bars to about 60 bars.

7. The method of claim 1, wherein the predetermined pressure is about 30 bars.

8. The method of claim 1, wherein the boron-containing film comprises at least one of boron oxide, amorphous boron, or a mixture of boron and carbon.

9. The method of claim 1, wherein the boron-containing film is a hardmask.

10. The method of claim 1, wherein the predetermined time is about 2 minutes to about 30 minutes.

11. The method of claim 1, wherein the predetermined time is about 5 minutes.

12. The method of claim 1, further comprising, prior to supplying the water vapor, heating a chamber wall of the process chamber to a temperature of about 250° C. to about 300° C.

13. A non-transitory computer readable storage medium having instructions stored thereon which when executed by a processer perform a method for processing a substrate comprising:
heating a substrate disposed in an interior volume of a process chamber and having a boron-containing film deposited thereon to a predetermined temperature; and
supplying water vapor in a non-plasma state to the interior volume at a predetermined pressure for a predetermined time, while maintaining the substrate at the predetermined temperature to anneal the substrate for the predetermined time and remove the boron-containing film.

14. The method of claim 13, further comprising supplying at least one of O₂, O₃, N₂O, CO₂, or CO while the water vapor is being supplied to the interior volume.

15. The non-transitory computer readable storage medium of claim 13, wherein the predetermined temperature is about 400° C. to about 500° C.

16. The non-transitory computer readable storage medium of claim 13, wherein the predetermined temperature is about 400° C. to about 500° C.

17. The non-transitory computer readable storage medium of claim 13, wherein the predetermined temperature is about 500° C.

18. The non-transitory computer readable storage medium of claim 13, wherein the predetermined pressure is about 20 bars to about 60 bars.

19. The non-transitory computer readable storage medium of claim 13, wherein the predetermined pressure is about 30 bars.

20. The non-transitory computer readable storage medium of claim 13, wherein the boron-containing film comprises at least one of boron oxide, amorphous boron, or a mixture of boron and carbon.
